(19) United States
(12) Patent Application Publication
(10) Pub. No.: US 2022/0209202 A1
(43) Pub. Date: Jun. 30, 2022

(54) Display Apparatus and Manufacturing Method of the Optical Film

(71) Applicant: LG Display Co., Ltd., Seoul (KR)

(72) Inventors: HyunJong Noh, Paju-si (KR); JungIm Hwang, Paju-si (KR); Suhyun Park, Paju-si (KR); Jinhyung Jung, Paju-si (KR)

(21) Appl. No.: 17/544,873

(22) Filed: Dec. 7, 2021

(30) Foreign Application Priority Data
Dec. 29, 2020 (KR) 10-2020-0186438

(51) Int. Cl. H01L 51/52; G02B 5/30; H01L 51/56

(52) U.S. Cl. CPC H01L 51/5281; G02B 5/3033; H01L 51/56; G02B 5/3016; G02B 5/3083

(57) ABSTRACT

Disclosed are a display apparatus and a manufacturing method of the optical film, the display apparatus comprising a display panel, wherein the optical film includes a polarizing layer disposed on the display panel, and a phase retardation layer disposed between the display panel and the polarizing layer, wherein the phase retardation layer includes a first phase retardation layer positioned adjacent to the display panel, and a second phase retardation layer covering the first phase retardation layer.

### CROSS-REFERENCE TO RELATED APPLICATIONS

This application claims the benefit of Korean Patent Application No. 10-2020-0186438 filed on Dec. 29, 2020, which is hereby incorporated by reference as if fully set forth herein.

### BACKGROUND

### Field of the Invention

The present disclosure relates to a display apparatus and a manufacturing method of the optical film, and more particularly, to a display apparatus comprising an optical film including a phase retardation layer prepared by simultaneously irradiating a plurality of polarized ultraviolet rays having different polarization axes.

### Discussion of the Related Art

A display apparatus displays an image through light emission of a light emitting device including a light emitting layer interposed between two electrodes. At this time, light generated according to an emission of an electroluminescent device is emitted to the outside through an electrode and a substrate.

The display apparatus has a high response speed and a low power consumption, and does not require a separate light source, unlike a liquid crystal display device. Thus, there is no problem in a viewing angle and is subject to attention as a next generation flat panel display apparatus.

However, the related art display apparatus uses an optical film including a polarizing layer and a phase retarder in order to control luminance and reflectance of a display panel. An optical film satisfying high luminance and low reflectance is expensive so that a technology for developing an optical film satisfying both cost and performance is required.

### SUMMARY

The present disclosure has been made in view of the above problems, and it is an object of the present disclosure to provide a display apparatus including an optical film having a phase retardation layer with reduced manufacturing cost.

It is another object of the present disclosure to provide a manufacturing method of an optical film including a phase retardation layer comprised of two layers having different polarization axes by simultaneously irradiating a first polarized ultraviolet ray and a second polarized ultraviolet ray in different directions in a process of preparing a phase retardation layer.

In accordance with an aspect of the present disclosure, the above and other objects can be accomplished by the provision of a display apparatus comprising a display panel, and an optical film disposed on a light exit surface of the display panel, wherein the optical film includes a polarizing layer disposed on the display panel, and a phase retardation layer disposed between the display panel and the polarizing layer, wherein the phase retardation layer includes a first phase retardation layer positioned adjacent to the display panel, and a second phase retardation layer covering the first phase retardation layer.

In accordance with another aspect of the present disclosure, there is provided a manufacturing method of an optical film comprising coating a phase retardation composition onto a substrate, exposing the phase retardation composition to polarized ultraviolet ray, and applying a heat treatment process to the phase retardation layer prepared by the exposing step, wherein the exposing includes irradiating first polarized ultraviolet ray toward a first surface of the phase retardation composition, and irradiating second polarized ultraviolet ray toward a second surface opposite to the first surface of the phase retardation composition.

### BRIEF DESCRIPTION OF THE DRAWINGS

The above and other objects, features and other advantages of the present disclosure will be more clearly understood from the following detailed description taken in conjunction with the accompanying drawings. In the drawings:

FIG. 1 illustrates a display apparatus according to the present disclosure;

FIG. 2 is a circuit diagram illustrating a first pixel shown in FIG. 1;

FIG. 3 is a cross sectional view illustrating a pixel including first to fourth pixels shown in FIG. 1;

FIG. 4 is an expanded view illustrating the first pixel shown in FIG. 3;

FIG. 5 is a cross sectional view illustrating an optical film according to the present disclosure;

FIG. 6 is a brief diagram illustrating a manufacturing method of a phase retardation layer of the optical film according to the present disclosure;

FIGS. 7A to 7E illustrate sequential steps in the manufacturing method of the phase retardation layer of the optical film shown in FIG. 6; and

FIG. 8 exemplarily illustrates an optical reaction mechanism of the phase retardation layer according to the manufacturing method shown in FIGS. 7A to 7E.

### DETAILED DESCRIPTION OF THE DISCLOSURE

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by the scopes of the appended claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known technology is determined to unnecessarily obscure the important point of the present disclosure, the detailed description will be omitted.

In a case where ‘comprise’, ‘have’, and ‘include’ described in the present disclosure are used, another part can be added unless ‘only-’ is used. The terms of a singular form can include plural forms unless referred to the contrary.

In describing a positional relationship, for example, when a position relation between two parts is described as ‘on-’, ‘over-’, ‘under-’, and ‘next-’, one or more other parts can be disposed between the two parts unless ‘just’ or ‘direct’ is used.

In describing a time relationship, for example, when the temporal order is described as ‘after-’, ‘subsequent-’, ‘next-’, and ‘before-’, a case which is not continuous can be included unless ‘just’ or ‘direct’ is used.

It will be understood that, although the terms “first,” “second,” and the like can be used herein to describe various elements, these elements should not be limited by these terms. These terms are only used to distinguish one element from another and may not define any order. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, embodiments of the present disclosure will be described in detail with reference to the accompanying drawings.

FIG. 1 illustrates a light emitting display apparatus according to the present disclosure.

Referring to FIG. 1, the light emitting display apparatus according to the present disclosure may include a display panel 10, a control circuit 30, a data driving circuit 50, and a gate driving circuit 70.

The display panel 10 includes a plurality of gate lines GL, a plurality of data lines DL, and a plurality of pixels 12a, 12b, 12c, and 12d formed in a pixel area defined by a plurality of gate lines GL and a plurality of data lines DL.

Each of the pixels 12a, 12b, 12c, and 12d displays an image according to a gate signal supplied from the adjacent gate line GL and a data signal supplied from the adjacent data line DL. Each of the plurality of pixels 12a, 12b, 12c, and 12d may include a pixel circuit prepared in the pixel area, and a light emitting device connected to the pixel circuit.

Each of the plurality of pixels 12a, 12b, 12c, and 12d may be defined as a region of a minimum unit in which actual light is emitted, and may be represented by a sub pixel. Herein, four adjacent pixels may constitute one unit pixel 12 for a color display.

One unit pixel 12 according to one embodiment of the present disclosure may include four pixels 12a, 12b, 12c, and 12d arranged adjacent to each other along the longitudinal direction of the gate line GL. For example, one unit pixel 12 may include first to fourth pixels 12a, 12b, 12c, and 12d. In this case, the first pixel 12a may be a red pixel, the second pixel 12b may be a green pixel, and the third pixel 12c may be a blue pixel, and the fourth pixel 12d may be a white pixel. The white pixel may be disposed between the blue pixel and the red pixel of the adjacent unit pixel 12, but not limited to this structure. The white pixel may be disposed between the red pixel and the green pixel in the unit pixel 12. The light emitting device of the first to fourth pixels 12a, 12b, 12c, and 12d according to one embodiment of the present disclosure may emit different color light or white light.

One unit pixel 120 according to another embodiment of the present disclosure may include first to third pixels 12a, 12b, and 12c without a fourth pixel 12d corresponding to a white pixel in the first to fourth pixels 12a, 12b, 12c, and 12d.

The control circuit 30 may generate pixel data for each pixel corresponding to each of the plurality of pixels 12a, 12b, 12c, and 12d based on video data input from the outside. The control circuit 30 may generate a data control signal based on a timing synchronization signal and may provide the generated data control signal to the data driving circuit 50. The control circuit 30 may generate a gate control signal based on the timing synchronization signal and may provide the gate control signal to the gate driving circuit 70.

The data driving circuit 50 may be connected to the plurality of data lines DL provided in the display panel 10. The data driving circuit 50 receives pixel data for each pixel provided from the control circuit 30 and the data control signal, and receives a plurality of reference gamma voltages provided from a power circuit. The data driving circuit 50 converts pixel data for each pixel into a data signal (or voltage) for each pixel by the use of the data control signal and the plurality of reference gamma voltages, and supplies the converted pixel data signal to the corresponding data line DL.

The gate driving circuit 70 may be connected to the plurality of gate lines GL prepared in the display panel 10. The gate driving circuit 70 generates a gate signal according to a predetermined order based on the gate control signal supplied from the control circuit 30, and supplies the gate signal to the corresponding gate line GL.

The gate driving circuit 70 according to one embodiment of the present disclosure may be integrated with one edge or both edges of the display panel 10 according to a manufacturing process of a thin film transistor, and may be connected with the plurality of gate lines GL in one-to-one correspondence. The gate driving circuit 70 according to another embodiment of the present disclosure may be configured as an integrated circuit, and mounted on a substrate or a flexible circuit film, and may be connected with the plurality of gate lines GL in one-to-one correspondence.

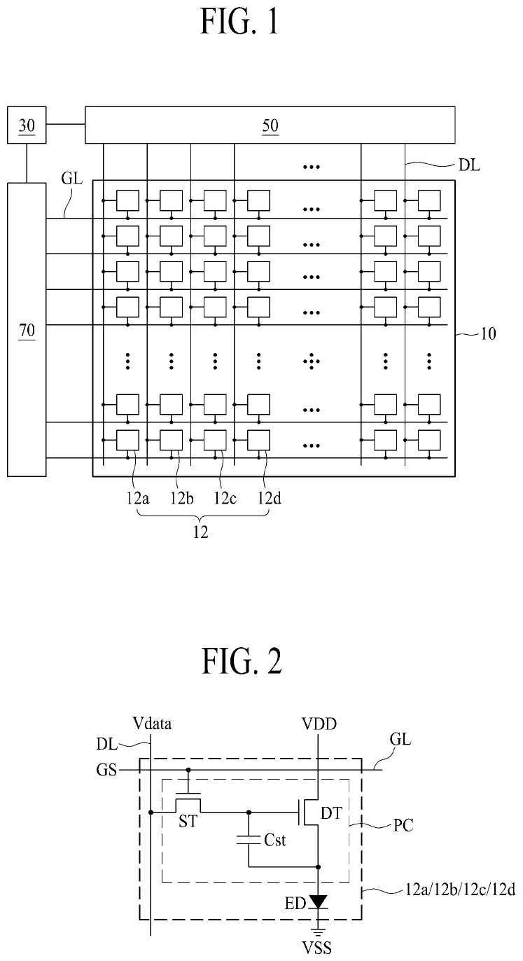

FIG. 2 is a circuit diagram illustrating the first pixel shown in FIG. 1.

Referring to FIG. 2, the first pixel 12a of the light emitting display apparatus according to the embodiment of the present disclosure includes a pixel circuit PC and an electroluminescent device ED.

The pixel circuit PC may be provided in a circuit portion in the pixel area defined by the gate line GL and the data line DL, and may be connected to the adjacent gate line GL and data line DL and a first driving power source VDD. The pixel circuit PC may control the light emission of the electroluminescent device ED according to the data signal Vdata from the data line DL in response to a gate-on signal GS from the gate line GL. The pixel circuit PC according to one embodiment of the present disclosure may include a switching thin film transistor ST, a driving thin film transistor DT, and a capacitor Cst. However, the configuration of the pixel circuit PC of the display apparatus according to the present disclosure is not limited thereto.

The switching thin film transistor ST may include a gate electrode connected to the gate line GL, a first source/drain electrode connected to the data line DL, and a second source/drain electrode connected to the gate electrode of the driving thin film transistor DT. The switching thin film transistor ST may be turned on according to the gate-on signal GS supplied to the gate line GL, and may supply the data signal Vdata supplied to the data line DL to the gate electrode of the driving thin film transistor DT.

The driving thin film transistor DT may include a gate electrode connected to a second source/drain electrode of the switching thin film transistor ST, a drain electrode connected to the first driving power source VDD, and a source electrode connected to the electroluminescent device ED. The driving thin film transistor DT may be turned on according to a gate-source voltage based on the data signal Vdata supplied from the switching thin film transistor ST, and may control a current (or a data current) supplied to the electroluminescent device ED from the first driving power source VDD.

The capacitor Cst is formed between the gate electrode of the driving thin film transistor DT and the source electrode (or overlap region), stores a voltage corresponding to the data signal Vdata supplied to the gate electrode of the driving thin film transistor DT, and turns on the driving thin film transistor DT with the stored voltage. At this time, the voltage stored in the capacitor Cst may be maintained until a new data signal Vdata is supplied through the switching thin film transistor ST in the next frame.

The electroluminescent device ED may be provided in an opening defined in the pixel area, and may emit light according to the current supplied from the pixel circuit PC.

The electroluminescent device ED according to one embodiment of the present disclosure may include a first electrode (or an anode electrode) connected to the pixel circuit PC, and a second electrode (or a cathode electrode) connected to a second driving power source VSS. For example, the electroluminescent device ED may include an organic light emitting device, a quantum dot light emitting device, or an inorganic light emitting device, or may include a micro light emitting diode device.

The first pixel 12a of the light emitting display apparatus according to one embodiment of the present disclosure displays a predetermined image through the light emission of the electroluminescent element ED according to the current corresponding to the data signal Vdata. Similarly, since each of the second, third, and fourth pixels 12b, 12c and 12d has the same configuration as the first pixel 12a, a description thereof will be omitted.

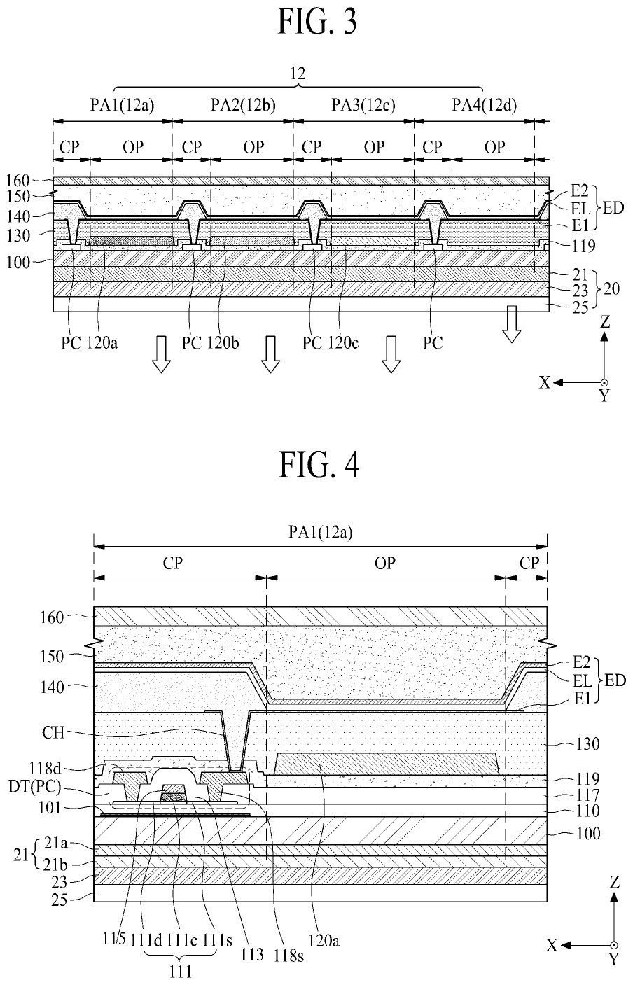

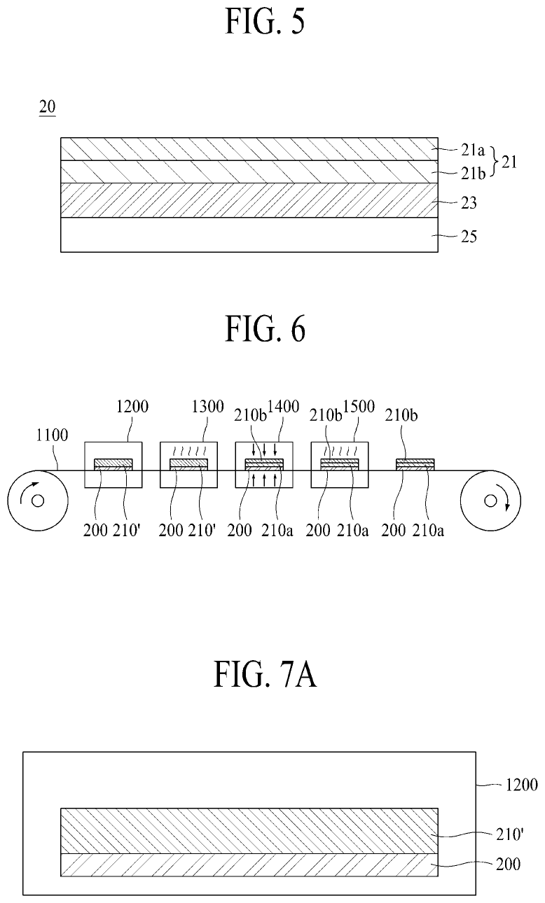

FIG. 3 is a view illustrating the display apparatus according to one embodiment of the present disclosure shown in FIG. 1, FIG. 4 is an enlarged view of the first pixel shown in FIG. 3, and FIG. 5 is a cross sectional view of the optical film according to the present disclosure. In FIGS. 3 and 4, it shows a bottom emission type in which the light source generated in the electroluminescent device ED is emitted toward the substrate 100, however, it is not limited to this bottom emission type. Therefore, the features described herein may be applied to the bottom emission type in which the optical film is disposed on the rear surface of the display panel, or a top emission type in which the optical film is disposed on the front surface of the display panel.

Referring to FIGS. 3 to 5, the display panel 10 according to one embodiment of the present disclosure may include the substrate 100, the pixel circuit PC, a protection layer 119, an overcoat layer 130, the electroluminescent device ED, and the optical film 20.

The substrate 100 may be made of a glass material, but may be made of a transparent plastic material, for example, polyimide, which may be bent or curved. When the plastic material is used as a material of the substrate 100, polyimide having excellent heat resistance that can withstand high temperature can be used in consideration of a high-temperature deposition process on the substrate 100. The entire surface of the substrate 100 may be covered by a buffer layer 110.

The buffer layer 110 prevents the material contained in the substrate 100 from diffusing into the transistor layer during the high temperature process of the manufacturing process of the thin film transistor. In addition, the buffer layer 110 may serve to prevent external moisture from penetrating into the light emitting display apparatus. The buffer layer 110 may be formed of silicon oxide or silicon nitride. Alternatively, the buffer layer 110 may be omitted.

The substrate 100 according to one embodiment of the present disclosure may include the plurality of pixel areas PA1, PA2, PA3, and PA4 having a circuit portion CP and an opening OP.

Four adjacent pixel areas among the plurality of pixel areas PA1, PA2, PA3, and PA4 may constitute one unit pixel area. For example, one unit pixel area may include first to fourth pixel areas PA1, PA2, PA3, and PA4. In this case, the first pixel area PA1 may be a red pixel area, a second pixel area PA2 may be a green pixel area, a third pixel area PA3 may be a blue pixel area, and a fourth pixel area PA4 may be a white pixel area.

The circuit portion CP may be defined as a transistor area defined in each of the plurality of pixel areas PA1, PA2, PA3, and PA4. The opening OP may be defined as a light extraction area in which light generated by the electroluminescent device ED disposed in each of the plurality of pixel areas PA1, PA2, PA3, and PA4 is extracted (or emitted) to the outside.

The pixel circuit PC shown in FIG. 3 represents the pixel circuit PC disposed on the circuit portion CP of the plurality of pixel areas PA1, PA2, PA3, and PA4, and may include a driving thin film transistor DT, a switching thin film transistor ST, and a capacitor Cst of the pixel circuit PC shown in FIG. 2.

The driving thin film transistor DT according to one embodiment of the present disclosure may include an active layer 111, a gate insulating film 113, a gate electrode 115, an insulating interlayer 117, a drain electrode 118d, and a source electrode 118s.

The active layer 111 may include a channel region 111c, a drain region 111d, and a source region 111s formed in a driving thin film transistor region of the circuit portion CP defined on the substrate 100 or the buffer layer 110. The active layer 111 may include a drain region 111d and a source region 111s which are conductive by an etching gas during an etching process of the gate insulating film 113, and a channel region 111c which is not conductive by the etching gas. The drain region 111d and the source region 111s may be spaced apart from each other with the channel region 111c therebetween.

The active layer 111 may be formed of any one of amorphous silicon, polycrystalline silicon, oxide, and organic material, but is not limited thereto. For example, the active layer 111 according to the present disclosure may be formed of an oxide such as Zinc Oxide, Tin Oxide, Ga—In—Zn-Oxide, In—Zn Oxide, or In—Sn-Oxide, or an oxide doped with ions of Al, Ni, Cu, Ta, Mo, Zr, V, Hf, or Ti.

The gate insulating film 113 may be formed on the channel region 111c of the active layer 111. The gate insulating film 113 is not formed on the entire surface of the substrate 100 or the buffer layer 110 including the active layer 111, and may be formed in an island shape only on the channel region 111c of the active layer 111.

The gate electrode 115 may be formed on the gate insulating film 113 to overlap the channel region 111c of the active layer 111. The gate electrode 115 serves as a mask to prevent the channel region 111c of the active layer 111 from being conductive by the etching gas during the patterning process of the gate insulating film 113 using the etching process. The gate electrode 115 may be made of molybdenum (Mo), aluminum (Al), chromium (Cr), gold (Au), titanium (Ti), nickel (Ni), neodymium (Nd), copper (Cu), or an alloy thereof, and may be composed of a single layer of metal or alloy or multiple layers of two or more layers.

The insulating interlayer 117 may be formed on the gate electrode 115, the drain region 111d and the source region ills of the active layer 111. The insulating interlayer 117 may be formed on the entire surface of the substrate 100 or the buffer layer 110 to cover the gate electrode 115, and the drain region 111d and the source region 111s of the active layer 111. The insulating interlayer 117 may be made of an inorganic material such as silicon oxide (SiOx), silicon nitride (SiNx), or the like.

The drain electrode 118d may be electrically connected to the drain region 111d of the active layer 111 through a first contact hole provided in the insulating interlayer 117 overlapped with the drain region 111d of the active layer 111.

The source electrode 118s may be electrically connected to the source region 111s of the active layer 111 through a second contact hole provided in the insulating interlayer 117 overlapped with the source region 111s of the active layer 111.

Each of the drain electrode 118d and the source electrode 118s is made of the same metal material, for example, molybdenum (Mo), aluminum (Al), chromium (Cr), gold (Au), titanium (Ti), nickel (Ni), neodymium (Nd), copper (Cu), or an alloy thereof, and may be comprised of a single layer of metal or alloy or multiple layers of two or more layers.

Since the switching thin film transistor has the same structure as the driving thin film transistor DT, a description thereof will be omitted.

The capacitor may be provided in an overlapping area between the source electrode 115s and the gate electrode 115 of the driving thin film transistor DT overlapping each other with the interlayer insulating film 117 therebetween.

Additionally, in order to prevent a threshold voltage in the thin film transistor provided in the circuit portion CP from being shifted by light, the light emitting display apparatus according to the present disclosure may further include a light shielding layer 101 provided under the active layer 111.

The light shielding layer 101 is provided between the substrate 100 and the active layer 111 to block light incident on the active layer 111 through the substrate 100, thereby minimizing or preventing a change in the threshold voltage of the transistor due to external light. The light shielding layer 101 may be covered by the buffer layer 110.

The protection layer 119 may be formed on the substrate 100 to cover the circuit layer. The protection layer 119 may be formed to cover the drain electrode, the source electrode, and the insulating interlayer of the thin film transistors disposed on the circuit portion CP. For example, the protection layer 119 may be made of an inorganic material such as silicon oxide (SiOx), silicon nitride (SiNx), or the like. Alternatively, the protection layer 119 may be expressed in terms of a passivation layer.

The overcoat layer 130 may be formed on the substrate 100 to cover the protection layer 119. The overcoat layer 130 according to one embodiment of the present disclosure may be relatively thick to provide a flat surface on the substrate 100. For example, the overcoat layer 130 may be formed of an organic material such as photo acryl, benzocyclobutene, polyimide, and fluorine resin. The overcoat layer 130 may be defined as a planarization layer.

The electroluminescent device ED may be disposed on the overcoat layer 130, and may emit light to the substrate 100 according to a bottom emission type by emitting light according to the data signal supplied from the driving thin film transistor DT of the pixel circuit PC.

The electroluminescent device ED according to one embodiment of the present disclosure includes a first electrode E1, an electroluminescent layer EL, and a second electrode E2.

The first electrode E1 may be formed on the overcoat layer 130, and may be overlapped with the opening OP of each of the plurality of pixel areas PA1, PA2, PA3, and PA4, and may be overlapped with at least a portion of the circuit portion CP.

At least a portion of the first electrode E1 may be electrically connected to the source electrode 118s of the driving thin film transistor DT through a contact hole CH provided in the overcoat layer 130 and the overcoat layer 130 in the circuit portion CP.

The first electrode E1 may be an anode electrode of the electroluminescent device ED. The first electrode E1 according to one embodiment of the present disclosure may include a transparent conductive material such as a transparent conductive oxide (TCO) so that the light emitted from the electroluminescent device ED may be transmitted to the substrate 100. For example, the first electrode E1 may be made of indium tin oxide (ITO) or indium zinc oxide (IZO).

The electroluminescent layer EL may be formed on the first electrode E1, and may directly contact the first electrode E1. The electroluminescent layer EL according to one embodiment of the present disclosure may include any one of an organic light emitting layer, an inorganic light emitting layer, and a quantum dot light emitting layer, or may include a stacked or mixed structure of an organic light emitting layer (or an inorganic light emitting layer) and a quantum dot light emitting layer.

The electroluminescent layer EL according to one embodiment of the present disclosure may include any one of a blue light emitting layer, a green light emitting layer, a red light emitting layer, and a white light emitting layer. For example, if the unit pixel includes first to fourth pixels 12a, 12b, 12c, and 12d, the electroluminescent layer EL disposed in the first pixel area PA1 may include a red light emitting layer, the electroluminescent layer EL disposed in the second pixel area PA2 may include a green light emitting layer, the electroluminescent layer EL disposed in the third pixel area PA3 may include a blue light emitting layer, and the electroluminescent layer EL disposed in the fourth pixel area PA4 may include a white light emitting layer, respectively. In this case, the electroluminescent layer EL of each of the first to fourth pixels 12a, 12b, 12c, and 12d may be disposed only on the first electrode E1 overlapped with the opening OP of each pixel area PA1, PA2, PA3, and PA4.

The electroluminescent layer EL according to another embodiment of the present disclosure includes two or more light emitting portions configured to emit white light. For example, when the unit pixel includes first to fourth pixels 12a, 12b, 12c, and 12d, the electroluminescent device ED in each of the first to fourth pixels 12a, 12b, 12c, and 12d may include a first light emitting portion and a second light emitting portion configured to emit white light by mixing the first light and the second light.

The first light emitting portion according to one example emits the first light, and may include any one of a blue light emitting portion, a green light emitting portion, a red light emitting portion, a yellow light emitting portion, and a yellowish green light emitting portion. The second light emitting portion according to one example may include any one of a blue light emitting portion, a green light emitting portion, a red light emitting portion, a yellow light emitting portion, and a yellowish green light emitting portion except the first light emitting portion. In this case, the electroluminescent layer EL may serve as a common layer of the first to fourth pixels 12a, 12b, 12c, and 12d, and may be disposed only on the first electrode E1 overlapped with the opening OP in each of the pixel areas PA1, PA2, PA3, and PA4, and also disposed to be overlapped with the circuit portion CP in each of the pixel areas PA1, PA2, PA3, and PA4.

Therefore, the light emitting devices of the first to fourth pixels 12a, 12b, 12c, and 12d according to one embodiment of the present disclosure may emit the same white light. In this case, each of the first to fourth pixels 12a, 12b, 12c, and 12d may include different wavelength conversion layers 120a, 120b, and 120c which convert white light into different color light. The fourth pixel 12d may emit white light toward the substrate 100 without having a wavelength conversion layer.

The second electrode E2 may be formed on the electroluminescent layer EL, and may directly contact the electroluminescent layer EL. The second electrode E2 according to one embodiment of the present disclosure may be a cathode electrode of the electroluminescent layer EL. The second electrode E2 according to one embodiment of the present disclosure may include a metal material having a high reflectance so as to reflect the light emitted from the electroluminescent layer EL toward the substrate 100. For example, the second electrode E2 may be formed in a multi-layered structure, for example, a deposition structure Ti/Al/Ti of aluminum (Al) and titanium (Ti), a deposition structure ITO/Al/ITO of aluminum (Al) and ITO, APC (Ag/Pd/Cu) alloy, and a deposition structure ITO/APC/ITO of APC alloy and ITO, or may be formed in a single-layered structure made of at least one material selected from silver (Ag), aluminum (Al), molybdenum (Mo), gold (Au), magnesium (Mg), calcium (Ca), or barium (Ba).

The display panel 10 according to the present disclosure may further include a bank pattern 140 and an encapsulation layer 150.

The bank pattern 140 defines the opening OP of each pixel area PA1, PA2, PA3, and PA4, and may be provided on the edge of the first electrode E1 and the overcoat layer 130. For example, the bank pattern 140 may be formed of an organic material such as benzocyclobutene(BCB)-based resin, acrylic resin, or polyimide resin. Alternatively, the bank pattern 140 may be formed of a photosensitive agent including a black pigment. In this case, the bank pattern 140 may serve as a light blocking member for preventing a color mixture between the adjacent pixels 12a, 12b, 12c, and 12d.

Each of the second electrode E2 and the electroluminescent device ED of the light emitting device ED may be formed on the bank pattern 140. That is, the electroluminescent device ED may be formed to cover the edge of the first electrode E1 and the bank pattern 140, and the second electrode E2 may be formed to cover the electroluminescent device ED.

The encapsulation layer 150 may be formed on the substrate 100 to cover the second electrode E2, that is, the entire pixel. The encapsulation layer 150 protects the thin film transistor and the electroluminescent device ED from an external shock, and serves to prevent oxygen, moisture, and particles from penetrating into the electroluminescent device ED.

The encapsulation layer 150 according to one embodiment of the present disclosure may include at least one inorganic film. The encapsulation layer 150 may further include at least one organic film. For example, the encapsulation layer 150 may include a first inorganic encapsulation layer, an organic encapsulation layer, and a second inorganic encapsulation layer. The first and second inorganic encapsulation layers may include any one inorganic material of a silicon oxide layer (SiOx), a silicon nitride layer (SiNx), a silicon oxynitride layer (SiON), a titanium oxide layer (TiOx), and an aluminum oxide layer (AlOx). The organic encapsulation layer may be made of any one organic material of acrylic resin, epoxy resin, phenolic resin, polyamide resin, polyimide resin, and benzocyclobutene resin. The organic encapsulation layer may be represented by a particle cover layer.

Selectively, the encapsulation layer 150 may be changed to a filler surrounding the entire pixel. In this case, the display panel 10 according to the present disclosure further includes an encapsulation substrate 160 attached to the substrate 100 via the filler. The encapsulation substrate 160 may be made of a plastic material, a glass material, or a metal material. The filler may include a getter material which absorbs oxygen and/or moisture.

In addition, when the electroluminescent device ED according to one embodiment of the present disclosure emits white light, the display panel 10 according to the present disclosure may further include wavelength conversion layers 120a, 120b, and 120c disposed to overlap each of the openings OP of the first to third pixel areas PA1, PA2, and PA3 among the pixel areas PA1, PA2, PA3, and PA4.

The wavelength conversion layers 120a, 120b, and 120c may be provided between the substrate 100 and the overcoat layer 130 while being overlapped with the opening OP. As an example, the wavelength conversion layers 120a, 120b, and 120c may be provided between the protection layer 119 and the overcoat layer 130 so as to overlap the opening OP. As another example, the wavelength conversion layers 120a, 120b, and 120c may be provided between the insulating interlayer 117 and the protection layer 119 to overlap with the opening OP, or between the substrate 100 (or the buffer layer 110) and the insulating interlayer 117 so as to overlap the opening OP.

The wavelength conversion layers 120a, 120b, and 120c according to one embodiment of the present disclosure may include a color filter which transmits only a wavelength of a predetermined color to the pixel among light emitted toward the substrate 100 from the electroluminescent element ED of the corresponding pixels 12a, 12b, and 12c. For example, the wavelength conversion layers 120a, 120b, and 120c may include a red color filter 120a overlapping the opening OP of the first pixel area PA1, a green color filter 120b overlapping the opening OP of the second pixel area PA2, and a blue color filter 120c overlapping the opening OP of the third pixel area PA3.

The wavelength conversion layer 120a, 120b, and 120c according to another embodiment of the present disclosure may include the quantum dot which has a size configured to re-emit light according to light emitted toward the substrate 100 from the electroluminescent device ED of the corresponding pixels 12a, 12b, and 12c so as to emit light of a predetermined color to the pixels. The quantum dot according to one embodiment of the present disclosure may be selected from CdS, CdSe, CdTe, CdZnSeS, ZnS, ZnSe, GaAs, GaP, GaAs-P, Ga-Sb, InAs, InP, InSb, AlAs, AlP, or AlSb so as to emit light of a color set in a pixel. For example, the wavelength conversion layers 120a, 120b, and 120c may include a red quantum dot pattern 120a overlapping the opening OP of the first pixel area PA1, a green quantum dot pattern 120b overlapping the opening OP of the second pixel area PA2, and a blue quantum dot pattern 120c overlapping the opening OP of the third pixel area PA3. As an example, the red quantum dot pattern 120a may include CdSe or InP, the green quantum dot pattern 120b may include a quantum dot of CdZnSeS, and the blue quantum dot pattern 120c may include a quantum dot of ZnSe. As described above, the light emitting display apparatus including the wavelength conversion layers 120a, 120b, and 120c with the quantum dots may have a high color reproduction rate.

The wavelength conversion layers 120a, 120b, and 120c according to another embodiment of the present disclosure may include a red color filter 120a containing a red quantum dot, a green color filter 120b containing a green quantum dot, and a blue color filter 120b containing a blue quantum dot. In this case, the red color filter 120a may not contain the red quantum dot so that the transmittance of light in the long wavelength region can be reduced.

In addition, when the display apparatus according to another embodiment of the present disclosure is the top emission type, the wavelength conversion layer may be provided on an upper portion of the electroluminescent device ED.

The optical film 20 may be disposed on the display panel 10 and may be disposed on a light exit surface. Specifically, the optical film 20 may be attached to the rear surface (or a second surface) opposite to the front surface (or the first surface) of the substrate 100.

The optical film 20 according to the present disclosure may include a phase retardation layer 21 disposed on the display panel 10, and a polarization layer 23 covering the phase retardation layer 21. Also, the optical film 20 may further include a protection member 25 configured to protect the polarization layer 23 so that the manufacturing process and manufacturing cost of the phase retardation layer can be reduced, and productivity can be improved.

According to one embodiment of the present disclosure, the phase retardation layer 21 may include a first phase retardation layer 21a disposed on the display panel 10, and a second phase retardation layer 21b covering the first phase retardation layer 21a.

The phase retardation layer 21 may include the first phase retardation layer 21a configured to delay incident light by ¼ wavelength λ/4, and the second phase retardation layer 21b configured to delay incident light by ½ wavelength λ/2.

The polarization layer 23 may be a linear polarizing layer and may transmit light parallel to the light transmission axis. That is, the light of the direction parallel to the polarization direction of the passing light passes, and the light of the vertical component is blocked.

The polarization layer 23 is disposed under the phase retardation layer 21. The polarization layer 23 transmits the light in parallel with the light transmission axis. That is, the light of the direction parallel to the polarization direction of the passing light passes, and the light of the vertical component is blocked.

The polarization layer 23 may have a linear polarization function using a polarizing film. The polarization layer 23 may include a polyvinyl alcohol (PVA) film. The polarization layer 23 can be manufactured by stretching the polyvinyl alcohol film in one direction and then adsorbing iodine (I) or dichroic dye. The polarization layer 23 has an absorption axis in the stretching direction and has a transmission axis in a direction perpendicular to the absorption axis. In the light incident on the polarization layer 23, only linearly polarized light is emitted in a direction parallel to the transmission axis. The polarization layer 23 may further include a tri-acetyl cellulose (TAC) film on the upper surface and the lower surface of the polarization layer 23 to compensate for durability to maintain mechanical strength, heat resistance, and moisture resistance of the polarizing film. The tri-acetyl cellulose (TAC) films have non-optical properties such that the characteristics of the light transmitted through the polarizing film are not changed, preferably.

The polarization layer 23 is formed by stretching the polyvinyl alcohol resin and arranging the iodine in one direction to induce anisotropy. The iodine can be separated from the polyvinyl alcohol resin at high temperatures. Since heat is generated when the inorganic film is deposited, it is difficult to form an inorganic film to be adjacent to the polarization layer. In this respect, after an encapsulation layer including a separate base film is formed, a polarization layer is formed thereon, thereby increasing thickness and reducing cost.

The combination of the polarization layer 23 and the phase retardation layer 21 can pass circularly polarized light rotating in a predetermined direction.

The protection member 25 may be configured to maintain the mechanical strength, heat resistance, and moisture resistance of the optical film 20, and thus may be formed of a transparent film having no phase delay or polarization characteristic, for example, tri-acetyl cellulose (TAC).

There may be an additional adhesive member (not shown) configured to fix the optical film 20 on the display panel 10 between the phase retardation layer 21 and the display panel 10. The adhesive member may include at least one of an optical clear adhesive (OCA) or a pressure sensitive adhesive (PSA).

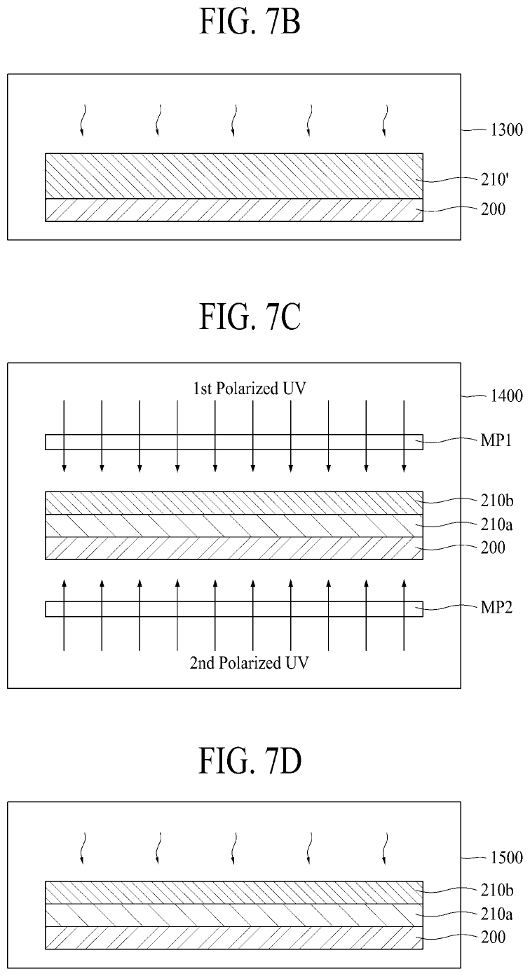

FIG. 6 is a schematic view of a method for manufacturing the phase retardation layer of the optical film according to the present disclosure, and FIGS. 7A to 7E illustrate sequential steps in the method of manufacturing the phase retardation layer of the optical film of FIG. 6.

Referring to FIGS. 6 and 7A to 7E, the phase retardation layer of the optical film may be prepared by performing an individual process using at least one substrate 200 moving device 1100.

Referring to FIG. 6, the phase retardation layer 21 of the optical film 20 may be prepared by a manufacturing apparatus of the phase retardation layer 21 including the moving device 1100, a coating device 1200, a drying device 1300, an exposure device 1400, and a heat treatment device 1500.

The phase retardation layer 21 of the optical film 20 on the substrate 200 may sequentially pass through the devices 1200, 1300, 1400, and 1500 by the moving device 1100 to apply a process of coating a phase retardation composition, a process of drying the applied phase retardation composition, a process of simultaneously irradiating a first polarized ultraviolet ray and a second polarized ultraviolet ray, and a heat treatment process, thereby forming the phase retardation layer 210 on the substrate 200.

At this time, the moving device 1100 may include a conveyor belt and a roller, and each process may be performed in an in-line manner, and may be performed in a roll-to-roll manner.

First, the substrate 200 is moved to the coating device 1200 by the moving device 1100, and the coating process for forming the phase retardation composition 210′ on the substrate 200 is carried out. The coating process for forming the phase retardation composition may use at least one of a spin-coating method, a slit-coating method, a doctor blade method, a spin-slit coating method, a roll to roll method, and a cast coating method.

Herein, the substrate 200 may be formed of a transparent material for a wavelength of the visible light region, for example, a transparent plastic substrate.

For example, the substrate 200 may be formed of at least one of polymethyl methacrylate, polycarbonate, polyvinyl chloride, triacetyl cellulose, and cyclo olefin polymer (COP).

Also, according to one embodiment of the present disclosure, the polarization layer 23 of the optical film 20 described above may be used as the substrate 200 described above.

Herein, the phase retardation composition is a photoalignment and photosensitive material, and the phase retardation composition is a liquid crystal polymer or a small molecule, an oligomer or a mixture thereof having a mesogen forming group exhibiting liquidity in a specific temperature section and a photosensitive group capable of exhibiting optical anisotropy by irradiating linearly polarized light. The phase retardation composition may be comprised of only a polymer except a photosensitive group, or may be comprised of a low molecular weight or an oligomer, or a mixture of a polymer and an oligomer. When the linearly polarized light is irradiated to the phase retardation composition, photo-isomerization is generated so that relatively very small optical anisotropy is formed, and optical anisotropy can be further increased through heat treatment above a specific temperature. The phase retardation composition may also have optical anisotropy, i.e., a phase difference axis after the exposure process. Therefore, the phase retardation layer 210 manufactured through the above processes includes a photo-alignment liquid crystal.

Next, the substrate 200 having the phase retardation composition 210′ is moved to the drying device 1300 using the moving device 1100 to remove the solvent from the phase retardation composition 210′. Drying may be carried out at a relatively low temperature that does not cause thermal shock to the phase retardation composition 210′. The drying process may be performed by a hot plate, an oven, or a natural drying method, and may use a drying method of radiation or convection using a far-infrared heater, an oven, or the like. The temperature of the drying process may be from about 25° C. to about 80° C., preferably from about 50° C. to about 70° C. for about 1 minute to about 10 minutes.

Next, the substrate 200 including the dried phase retardation composition 210′ is moved to the exposure device 1400 by the moving device 1100 to perform an exposure process, thereby forming the phase retardation layer 210 having a first phase retardation layer 210a adjacent to the substrate 200 and a second phase retardation layer 210b covering the first phase retardation layer 210a.

In the exposure process, the linearly polarized light is irradiated to the phase retardation composition 210′ so that the phase retardation composition 210′ has optical anisotropy, wherein the linearly polarized light has a wavelength of 200 nm to 400 nm, and more preferably, a wavelength in the range of 254 nm to 365 nm. At this time, the exposure energy of the polarized ultraviolet ray is 1 mJ/cm² to 1000 mJ/cm², and preferably, the phase retardation composition 210 can be set at 50 mJ/cm² to 150 mJ/cm² with an energy that can exhibit a maximum anisotropy.

Herein, the first polarized ultraviolet ray and the second polarized ultraviolet ray may be set to be different from each other, and for example, the polarization axis of the first polarized ultraviolet ray may have an angle range of 40 to 100 degrees with the polarization axis of the second polarized ultraviolet ray.

In order to set the polarization axes of the first polarized ultraviolet ray and the second polarized ultraviolet ray to be different from each other, a first mask pattern MP1 and a second mask pattern MP2 for filtering the first polarized ultraviolet ray may be prepared to have different optical axes.

The phase retardation layer 21 according to the present disclosure is advantageous in that the first phase retardation layer 21a and the second phase retardation layer 21b are formed by simultaneously irradiating the first polarized ultraviolet UV and the second polarized UV, thereby shortening the manufacturing process and reducing costs.

Herein, the simultaneous irradiation of the first polarized UV and the second polarized UV light may mean that the first polarized UV and the second polarized UV are simultaneously irradiated or the first polarized UV is irradiated from the exposure device 1400, and the second polarized UV is sequentially irradiated from the exposure device 1400.

According to one embodiment, the first phase retardation layer 21a and the second phase retardation layer 21b may have different polarization axes. By the above-described process, the phase retardation layer 21 including the first phase retardation layer 21a and the second phase retardation layer 21b having different phase difference axes may be prepared.

Next, the substrate 200 having the phase retardation layer 21 including the first phase retardation layer 21a and the second phase retardation layer 21b is moved to the heat treatment device 1500 by the moving device 1100, thereby performing a heat treatment process.

The heat treatment process is a process of amplifying the optical anisotropy of the phase retardation layer 21 including the first phase retardation layer 21a and the second phase retardation layer 21b so that no direct heat is applied to the phase retardation layer 21 including the first phase retardation layer 21a and the second phase retardation layer 21b, thereby preventing thermal shock. As a result, a haze phenomenon where the phase retardation layer 21 including the first phase retardation layer 21a and the second phase retardation layer 21b is scattered is avoided, thereby obtaining a transparent film in the visible light region. It is preferable to use a radiation or convection phenomenon by a far-infrared heater, an oven, etc. In the heat treatment process, the temperature of the phase retardation layer 21 including the first phase retardation layer 21a and the second phase retardation layer 21b may be set to be higher than the temperature of the drying process. The heat treatment process may be performed at 80° C. to 150° C., and may be performed for about 1 minute to about 30 minutes.

Next, the substrate 200 including the phase retardation layer 210 in which the heat treatment process is completed may be moved through the moving device 1100, and may be wound using a roll as shown in FIG. 6.

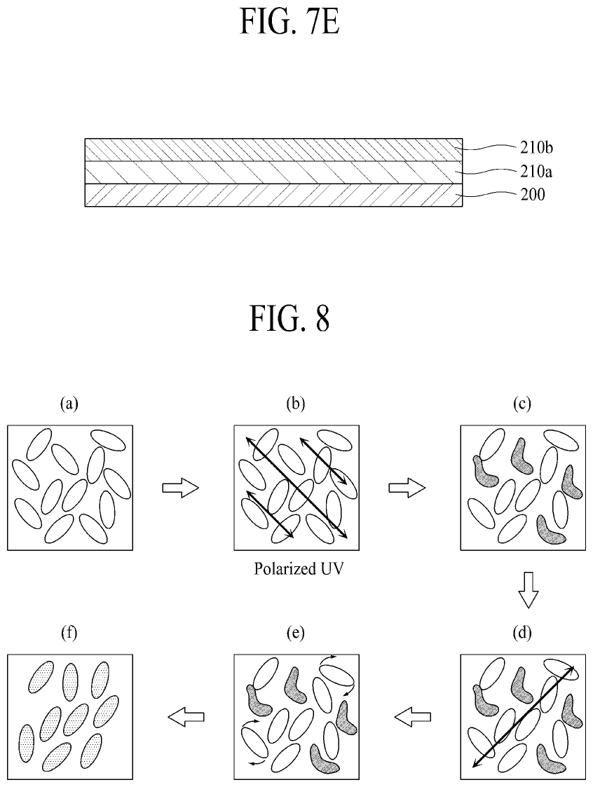

FIG. 8 illustrates the optical reaction mechanism of the phase retardation layer according to the manufacturing method of FIGS. 7A to 7E. FIG. 8 illustrates an optical reaction mechanism in which an anisotropic property is formed in the phase retardation composition by FIGS. 7C and 7D to form the first phase retardation layer 210a and the second phase retardation layer 210b, and the phase retardation composition of FIG. 8 may include a photoreactive liquid crystal polymer.

First, FIG. 8, part (a) shows an initial chaotic arrangement of the phase retardation composition. Here, the phase retardation composition may include a photoreactive liquid crystal polymer.

Next, FIG. 8, part (b) shows irradiating linearly polarized UV to the phase retardation composition having a disordered array state.

Referring to FIG. 8, part (c), a Z-isomer is formed by an axis-selective optical reaction when the linearly polarized UV is irradiated to the phase retardation composition having the disordered array state. Also, as shown in FIG. 8, part (d), the phase retardation composition may have a weak anisotropy after an axis-selective photochemical reaction by irradiating the linearly polarized UV light.

Referring to FIG. 8, part (e), when the heat treatment is performed on the phase retardation composition having a weak anisotropy, a self-orientation phenomenon according to the heat treatment is shown. It can be seen from FIG. 8, part (f) that the anisotropy of FIG. 8 is increased by being aligned in one direction by the self-orientation.

The display apparatus and the method for manufacturing the optical film according to the present disclosure may be described as follows.

The display apparatus according to the present disclosure comprises the display panel, and the optical film disposed on the light exit surface of the display panel, wherein the optical film includes the polarizing layer disposed on the display panel, and the phase retardation layer disposed between the display panel and the polarizing layer, wherein the phase retardation layer includes the first phase retardation layer positioned adjacent to the display panel, and the second phase retardation layer covering the first phase retardation layer.

According to one embodiment of the present disclosure, the polarizing layer may be the linear polarizing layer.

According to one embodiment of the present disclosure, the phase retardation layer may include the photo-alignment liquid crystal.

According to one embodiment of the present disclosure, the first phase retardation layer has an anisotropy of the first direction by the first polarized ultraviolet ray, and the second phase retardation layer may have the anisotropy in the second direction crossing the first direction by the second polarized ultraviolet ray.

According to one embodiment of the present disclosure, the polarization axis of the first polarized ultraviolet ray may range from 40 to 100 degrees with the polarization axis of the second polarized ultraviolet ray.

According to one embodiment of the present disclosure, the first polarized ultraviolet ray and the second polarized ultraviolet ray may have a wavelength selected at a wavelength of 254 nm to 365 nm.

According to one embodiment of the present disclosure, the first polarized ultraviolet ray and the second polarized light may be irradiated at an exposure energy of 150 mJ/cm² to 150 mJ/cm².

The method for manufacturing the optical film according to the present disclosure comprises the steps of applying the phase retardation composition on the substrate; exposing the phase retardation composition to the polarized ultraviolet ray, and heat-treating the phase retardation layer prepared by the exposing step, wherein the exposing includes irradiating the first polarized ultraviolet ray toward the first surface of the phase retardation composition, and irradiating the second polarized ultraviolet ray toward the second surface opposite to the first surface of the phase retardation composition.

According to one embodiment of the present disclosure, the phase retardation layer may include the photo-alignment liquid crystal.

According to one embodiment of the present disclosure, the first phase retardation layer has the anisotropy of the first direction by the first polarized ultraviolet ray, and the second phase retardation layer may have the anisotropy in the second direction crossing the first direction by the second polarized ultraviolet ray.

According to one embodiment of the present disclosure, the polarization axis of the first polarized ultraviolet ray may range from 40 to 100 degrees with the polarization axis of the second polarized ultraviolet ray.

According to one embodiment of the present disclosure, the first polarized ultraviolet ray and the second polarized ultraviolet ray may have a wavelength selected at a wavelength of 254 nm to 365 nm.

According to one embodiment of the present disclosure, the first polarized ultraviolet ray and the second polarized ultraviolet ray may be irradiated with exposure energy of 50 mJ/cm² to 150 mJ/cm².

According to the embodiments of the present disclosure, it is possible to provide the display apparatus with the improved productivity by reducing the manufacturing process and manufacturing cost of the phase retardation layer.

According to the embodiments of the present disclosure, it is possible to provide the manufacturing method of the optical film with the improved productivity by reducing the manufacturing process and manufacturing cost of the phase retardation layer.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A display apparatus comprising:
a display panel; and
an optical film disposed on a light exit surface of the display panel,
wherein the optical film includes:
a polarizing layer disposed on the display panel; and
a phase retardation layer disposed between the display panel and the polarizing layer, and
wherein the phase retardation layer includes a first phase retardation layer positioned adjacent to the display panel, and a second phase retardation layer covering the first phase retardation layer.

2. The display apparatus according to claim 1, wherein the polarizing layer is a linear polarizing layer.

3. The display apparatus according to claim 1, wherein the phase retardation layer includes a photo-alignment liquid crystal.

4. The display apparatus according to claim 1, wherein the first phase retardation layer has an anisotropy of a first direction by a first polarized ultraviolet ray, and the second phase retardation layer has an anisotropy in a second direction crossing the first direction by a second polarized ultraviolet ray.

5. The display apparatus according to claim 4, wherein an angle between a first polarization axis of the first polarized ultraviolet ray and a second polarization axis of the second polarized ultraviolet ray ranges from 40 to 100 degrees.

6. The display apparatus according to claim 4, wherein the first polarized ultraviolet ray and the second polarized ultraviolet ray may have a wavelength of 254 nm to 365 nm.

7. The display apparatus according to claim 4, wherein the first polarized ultraviolet ray and the second polarized light are irradiated at an exposure energy of 50 mJ/cm² to 150 mJ/cm².

8. A manufacturing method of an optical film, the manufacturing method comprising:
coating a phase retardation composition onto a substrate;
exposing the phase retardation composition to polarized ultraviolet ray; and
applying a heat treatment process to a phase retardation layer prepared by the exposing step,
wherein the exposing includes irradiating a first polarized ultraviolet ray toward a first surface of the phase retardation composition, and irradiating a second polarized ultraviolet ray toward a second surface opposite to the first surface of the phase retardation composition.

9. The manufacturing method according to claim 8, wherein the phase retardation layer includes a photo-alignment liquid crystal.

10. The manufacturing method according to claim 8,
wherein at least a portion of the phase retardation layer has an anisotropy of a first direction by the step of irradiating the first polarized ultraviolet ray toward the first surface of the phase retardation composition, and
remaining portions except the phase retardation layer having the anisotropy of the first direction have an anisotropy of a second direction crossing the first direction by the step of irradiating the second polarized ultraviolet ray toward the second surface opposite to the first surface of the phase retardation composition.

11. The manufacturing method according to claim 10, wherein an angle between a first polarization axis of the first polarized ultraviolet ray and a second polarization axis of the second polarized ultraviolet ray ranges from 40 to 100 degrees.

12. The manufacturing method according to claim 10, wherein the first polarized ultraviolet ray and the second polarized ultraviolet ray have a wavelength of 254 nm to 365 nm.

13. The manufacturing method according to claim 10, wherein the first polarized ultraviolet ray and the second polarized ultraviolet ray are irradiated with exposure energy of 50 mJ/cm² to 150 mJ/cm².
